(19) United States
(12) Patent Application Publication
(10) Pub. No.: US 2012/0162881 A1
(43) Pub. Date: Jun. 28, 2012

(54) MOBILE DEVICE

(75) Inventor: Yasunori USUI, Tokyo (JP)

(73) Assignee: Casio Computer Co., Ltd., Tokyo (JP)

(21) Appl. No.: 13/331,475

(22) Filed: Dec. 20, 2011

(30) Foreign Application Priority Data
Dec. 22, 2010 (JP) 2010-285434
Jan. 7, 2011 (JP) 2011-001670

(51) Int. Cl. H05K 5/03

(52) U.S. Cl. 361/679.01

(57) ABSTRACT

A mobile device of the present invention includes a cover member which covers the opening section of a storage section provided in the device case. The cover member includes an outer cover section which forms a portion of the outer shape of the device case, and an inner cover section which is attached to the inner side of the outer cover section and detachably inserted into the opening section of the storage section. In addition, a gasket groove which is open in two directions perpendicular to each other toward the outer cover section side and the outer peripheral side of the inner cover section is provided in the outer peripheral portion of the inner cover section along the outer periphery of the inner cover section, so as to be located closer to the center side than the outer periphery of the outer cover section.

### CROSS-REFERENCE TO RELATED APPLICATIONS

This application is based upon and claims the benefit of priority from the prior Japanese Patent Applications No. 2010-285434, filed Dec. 22, 2010 and No. 2011-001670, filed Jan. 7, 2011, the entire contents of which are incorporated herein by reference.

### BACKGROUND OF THE INVENTION

1. Field of the Invention

The present invention relates to a mobile device, such as personal digital assistants (PDA), mobile information terminals (handy terminals), mobile phones, portable personal computers, and electronic cameras.

2. Description of the Related Art

As described in Japanese Patent Application Laid-Open (Kokai) Publication No. 2004-157240, a battery cover used in an electronic camera is known for having a structure such that, when openably and closably covering a battery storage section provided inside a camera case, the inner side portion of its body is inserted into the opening section of the battery storage section, and a waterproofing gasket provided on the outer peripheral portion of the inserted inner side portion of the cover body comes in close contact with the inner peripheral surface of the opening section of the battery storage section, thereby achieving waterproofing.

In the battery cover of an electronic camera such as this, a gasket groove is formed in the outer peripheral surface of the inner portion of the cover body that is inserted into the opening section of the battery storage section, continuously along the outer periphery so as to be open only on the outer peripheral side. The waterproofing gasket is inserted into this gasket groove, and a portion of the inserted waterproofing gasket protrudes from the gasket groove towards the outer peripheral side. Then, when the inner portion of the cover body is inserted into the opening section of the battery storage section in this state, the portion of the waterproofing gasket protruding from the gasket groove elastically comes in close contact with the inner peripheral surface of the opening section of the battery storage section.

However, in this battery cover of an electronic camera, the gasket groove in the outer peripheral surface of the inner portion of the cover body is formed to be open only on the outer peripheral side of the cover body. Accordingly, in cases where the cover body is molded using a mold for molding, the gasket groove cannot be formed on the outer peripheral surface of the cover body unless a slide mechanism is provided inside the mold. As a result, the structure of the mold becomes complex. Therefore, there is a problem in that the manufacturing of the mold is complicated, and the cost of the mold and the price of the product become expensive.

### SUMMARY OF THE INVENTION

An object of the present invention is to enable a mold for molding to be manufactured with a simple structure at low cost, and to ensure the waterproofing of a mobile device.

In order to achieve the above-described object, in accordance with one aspect of the present invention, there is provided a mobile device comprising a cover member which covers an opening section of a storage section provided in a device case; wherein the cover member includes an outer cover section which forms a portion of outer shape of the device case, and an inner cover section which is attached to inner side of the outer cover section and detachably inserted into the opening section of the storage section; and a gasket groove which is open in two directions perpendicular to each other toward outer cover section side and outer peripheral side of the inner cover section is provided in an outer peripheral portion of the inner cover section along outer periphery of the inner cover section, so as to be located closer to a center side than outer periphery of the outer cover section.

In accordance with another aspect of the present invention, there is provided a mobile device comprising a cover member which covers an opening section of a storage section provided in a device case; wherein the cover member includes an outer cover section which forms a portion of outer shape of the device case, and an inner cover section which is fixed to inner side of the outer cover section and detachably inserted into the opening section of the storage section; engaging hook sections are formed on inner surface of the outer cover section, which detachably engage with locking groove sections which are respectively provided in outer side portions of the device case and located on sides of the storage section; and a gasket groove is circularly formed in an outer peripheral portion of the inner cover section along entire periphery, which is opposed and located close to the engaging hook sections of the outer cover section.

According to the present invention, a mold for molding can be manufactured with a simple structure at low cost, and the waterproofing of a mobile device can be ensured.

In addition, according to the present invention, when the inner cover section that is detachably inserted into the opening section of the storage section provided in the device case is attached to the inner side of the outer cover section which forms a portion of the outer shape of the device case, the gasket groove formed in the outer peripheral portion of the inner cover section is covered by the outer cover section, and therefore is open only on the outer peripheral side of the inner cover section. Accordingly, the waterproofing gasket is favorably and reliably fitted in the gasket groove that is open only on the outer peripheral side of the inner cover section, whereby the waterproofing of the mobile device is ensured.

Moreover, according to the present invention, the waterproofing gasket is fitted in the gasket groove of the inner cover section fixed to the inner surface of the outer cover section, the inner cover section is inserted into the opening section of the storage section of the device case, and the outer cover section is pressed against the device case, when the cover member covers the storage section of the device case. As a result, the engaging hook sections of the outer cover section are engaged with the locking groove sections provided in the outer side portions on both sides of the device case, with the waterproofing gasket being in close contact with the inner peripheral surface of the opening section of the storage section.

The above and further objects and novel features of the present invention will more fully appear from the following detailed description when the same is read in conjunction with the accompanying drawings. It is to be expressly understood, however, that the drawings are for the purpose of illustration only and are not intended as a definition of the limits of the invention.

### BRIEF DESCRIPTION OF THE DRAWINGS

FIG. 1 is a front view of a first embodiment in which the present invention has been applied to a mobile information terminal;

FIG. 2 is a perspective view of the mobile information terminal shown in FIG. 1 when viewed from the back surface side;

FIG. 3 is an enlarged cross-sectional view of the mobile information terminal taken along line A-A in FIG. 2;

FIG. 4 is an enlarged perspective view of the battery cover of the mobile information terminal shown in FIG. 2 when viewed from obliquely above;

FIG. 5 is an enlarged perspective view of the battery cover of the mobile information terminal shown in FIG. 4 when viewed from obliquely below;

FIG. 6 is an enlarged perspective view of the battery cover of the mobile information terminal shown in FIG. 5, in which the waterproofing gasket has been removed;

FIG. 7 is an enlarged rear view of the battery cover shown in FIG. 6 when viewed from below;

FIG. 8 is an enlarged cross-sectional view of the battery cover taken along line B-B in FIG. 5;

FIG. 9 is a further enlarged cross-sectional view of the main section of the battery cover shown in FIG. 8;

FIG. 10 is an enlarged perspective view of the outer cover section of the battery cover shown in FIG. 6 when viewed from obliquely below;

FIG. 11 is an enlarged perspective view of the inner cover section of the battery cover shown in FIG. 6 when viewed from obliquely above;

FIG. 12 is an enlarged perspective view of the inner cover section of the battery cover shown in FIG. 11 when viewed from obliquely below;

FIG. 13 is an enlarged side view of the inner cover section shown in FIG. 11 when viewed from the side;

FIG. 14 is an enlarged perspective view of the waterproofing gasket of the battery cover shown in FIG. 5;

FIG. 15 is a front view of a second embodiment in which the present invention has been applied to a mobile information terminal;

FIG. 16 is a perspective view of the mobile information terminal shown in FIG. 15 when viewed from the back surface side;

FIG. 17 is an enlarged perspective view of the mobile information terminal shown in FIG. 16, in which the battery cover is open at a predetermined angle;

FIG. 18 is an enlarged perspective view of the main section of the mobile information terminal taken along line A-A in FIG. 17;

FIG. 19 is an enlarged perspective view of the battery cover of the mobile information terminal shown in FIG. 16;

FIG. 20 is an enlarged rear view of the battery cover of the mobile information device shown in FIG. 19 when viewed from the back surface side;

FIG. 21A and FIG. 21B are cross-sectional views of the battery cover taken along line B-B in FIG. 20, in which FIG. 21A is an enlarged cross-sectional view showing a state in which the waterproofing gasket has been fitted in the gasket groove, and FIG. 21B is an enlarged cross-sectional view showing a state in which the waterproofing gasket has been removed from the gasket groove;

FIG. 22A and FIG. 22B are further enlarged views of the main section of the battery cover shown in FIG. 21, in which FIG. 22A is an enlarged cross-sectional view of the main section where the waterproofing gasket has been fitted in the gasket groove, and FIG. 22B is an enlarged cross-sectional view of the main section where the waterproofing gasket has been removed from the gasket groove;

FIG. 23A and FIG. 23B are cross-sectional views of the battery cover taken along line C-C in FIG. 20, in which FIG. 23A is an enlarged cross-sectional view showing a state in which the waterproofing gasket has been fitted in the gasket groove, and FIG. 23B is an enlarged cross-sectional view showing a state in which the waterproofing gasket has been removed from the gasket groove;

FIG. 24A and FIG. 24B are further enlarged views of the main sections of the battery cover shown in FIG. 23A and FIG. 23B, in which FIG. 24A is an enlarged cross-sectional view of the main section where the waterproofing gasket has been fitted in the gasket groove, and FIG. 24B is an enlarged cross-sectional view of the main section where the waterproofing gasket has been removed from the gasket groove;

FIG. 25A to FIG. 25C are diagrams showing the outer cover section of the battery cover in FIG. 20, in which FIG. 25A is an enlarged rear view of the outer cover section, FIG. 25B is an enlarged cross-sectional view of the outer cover section taken along line D-D in FIG. 25A, and FIG. 25C is an enlarged cross-sectional view of the outer cover section taken along line E-E in FIG. 25A;

FIG. 26A to FIG. 26C are diagrams showing the inner cover section of the battery cover in FIG. 20, in which FIG. 26A is an enlarged rear view of the inner cover section, FIG. 26B is an enlarged cross-sectional view of the inner cover section taken along line F-F in FIG. 26A, and FIG. 26C is an enlarged cross-sectional view of the inner cover section taken along line G-G in FIG. 26A; and

FIG. 27 is an enlarged perspective view of the waterproofing gasket of the battery cover shown in FIG. 21A.

### DETAILED DESCRIPTION OF THE PREFERRED EMBODIMENTS

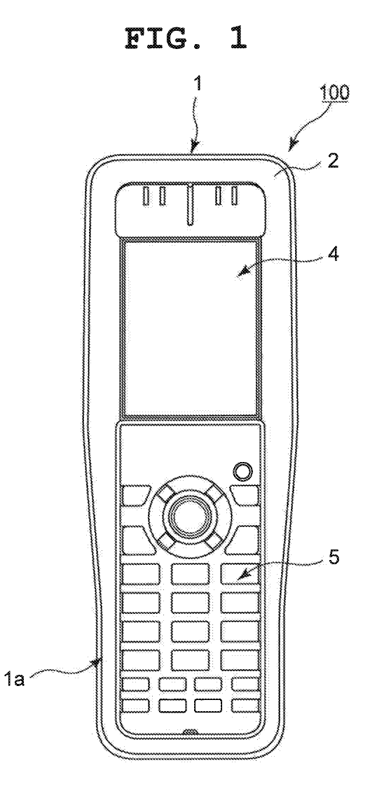

A first embodiment in which the present invention has been applied to a mobile information terminal 100 will be described with reference to FIG. 1 to FIG. 14.

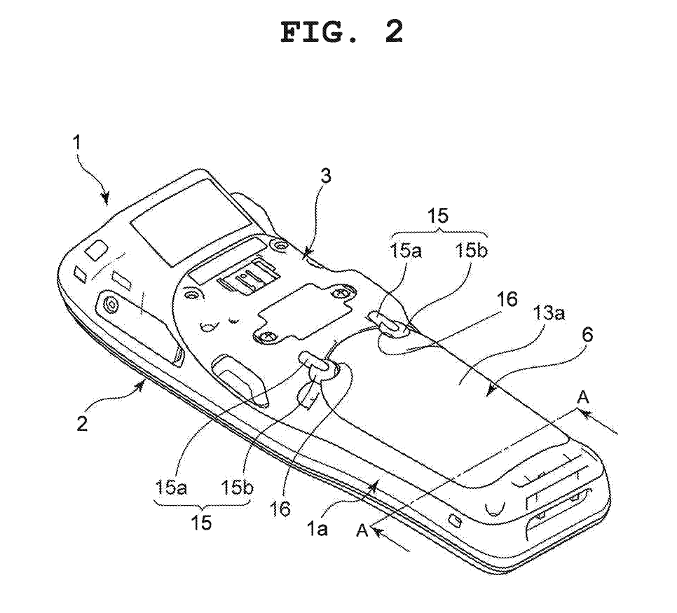

As shown in FIG. 1 and FIG. 2, the mobile information terminal 100 includes a device case 1. The device case 1 is constituted by an upper case 2 and a lower case 3, and a display section 4 and a key input section 5 are provided inside the device case 1 such that they are exposed on the top surface side of the upper case 2. In addition, a battery cover 6 is detachably attached to the undersurface of the lower case 3.

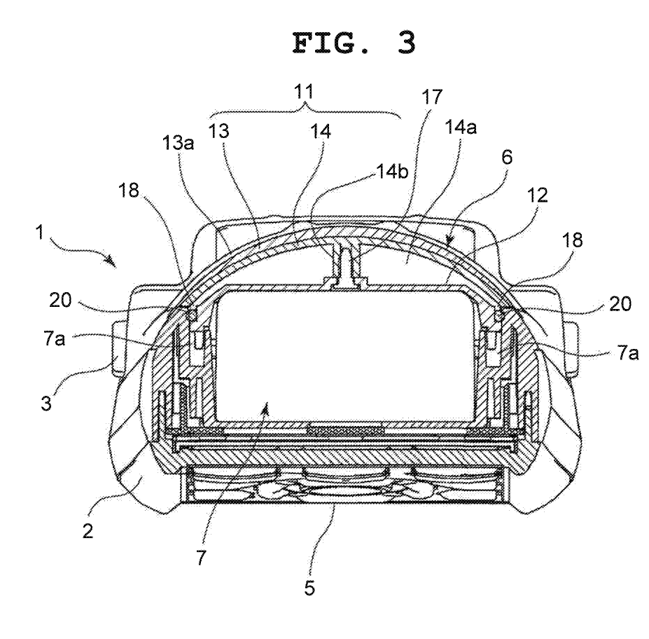

In this instance, the display section 4 includes a flat-screen display panel, such as a liquid crystal display panel or an electroluminescent (EL) display panel, and is structured to electro-optically display various information related to information processing. The key input section 5 includes various keys required for information processing, such as character keys, cursor keys, and function keys. In addition, as shown in FIG. 3, a battery storage section 7 for storing a battery (not shown) is provided inside the lower case 3, corresponding to the lower portion of the key input section 5. This battery storage section 7 is open on the underside of the lower case 3 (upper side in FIG. 2).

As shown in FIG. 1 and FIG. 2, the overall device case 1 is formed into a substantially rectangular box shape elongated in the front-back direction (up-down direction in FIG. 1). The length of the device case 1 in the width direction (left-right direction in FIG. 1) perpendicular to the front-back direction is formed such that the upper edge side where the display section 4 is provided is slightly longer than the lower edge side where the key input section 5 is provided, as shown in FIG. 1.

Accordingly, a portion of the device case 1 on the lower edge side where the key input section 5 is located is formed into a gripping section 1a. That is, the device case 1 is structured so that the user holds the gripping section 1a on the lower edge side where the key input section 5 is located by gripping it in one hand, and performs input operation of the key input section 5 while viewing information displayed in the display section 4.

The battery cover 6 is structured to openably and closably cover an opening section 7a of the battery storage section 7 provided in a portion of the lower case 3 corresponding to the key input section 5, as shown in FIG. 2 and FIG. 3. This battery cover 6 includes an outer cover section 11 that forms a portion of the outer shape of the lower case 3, and an inner cover section 12 that is arranged by being attached to the inner side (underside in FIG. 3) of the outer cover section 11 and detachably inserted into the opening section 7a of the battery storage section 7 provided in the lower case 3, as shown in FIG. 3 to FIG. 6.

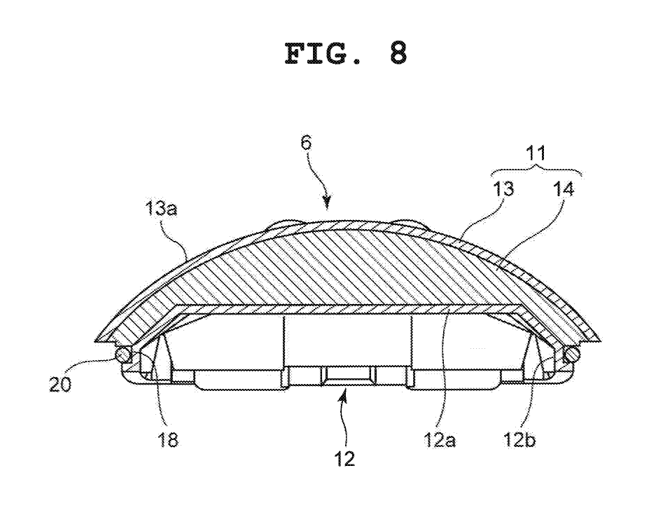

The outer cover section 11 includes a first cover section 13 made of a soft synthetic resin and a second cover section 14 made of a synthetic resin that is harder than the soft synthetic resin, which are integrally formed by two-color formation, as shown in FIG. 3 to FIG. 8. In this instance, the first cover section 13 is made of a soft synthetic resin having elasticity, such as rubber or elastomer, and located on the outer side (upper side in FIG. 8) of the lower case 3.

In addition, the outer peripheral surface (top surface in FIG. 3) of the first cover section 13 is formed into a curved surface 13a that is continuous with the undersurface of the lower case 3, as shown in FIG. 2 and FIG. 3. Accordingly, when the user grips the gripping section 1a of the device case 1, the first cover section 13 closely fits in the user's palm by the curved surface 13a of the first cover section 13.

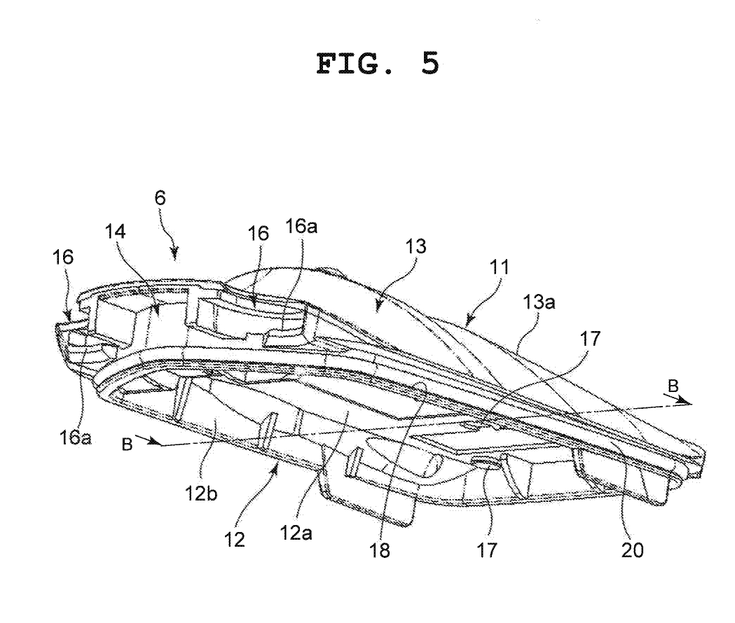

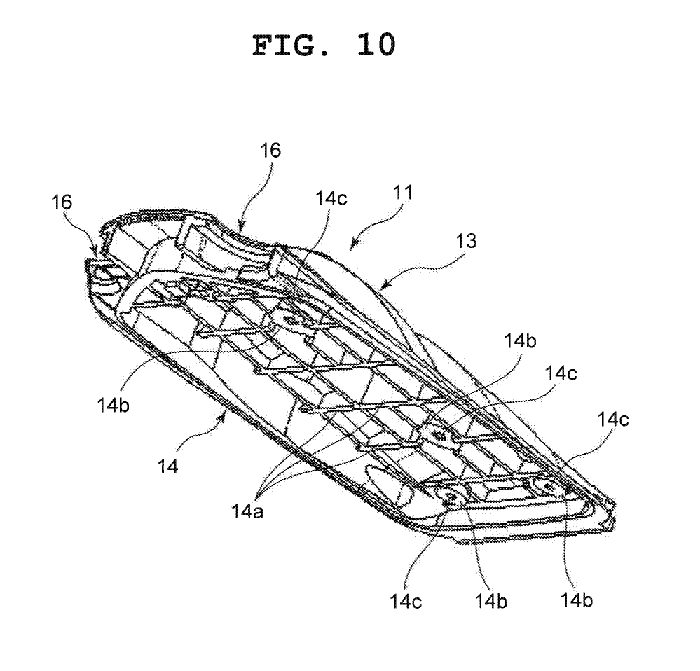

The second cover section 14 is made of a hard synthetic resin, such as acrylonitrile butadiene styrene (ABS) resin or polycarbonate (PC), and located on the inner side (underside in FIG. 8) opposing the undersurface of the lower case 3, as shown in FIG. 5 to FIG. 8. As shown in FIG. 10, reinforcement ribs 14a are formed vertically and horizontally in a lattice shape on the inner surface (undersurface in FIG. 8) of the second cover section 14, and a plurality of boss sections 14b each having a screw hole 14c are formed in predetermined areas of the reinforcement ribs 14a.

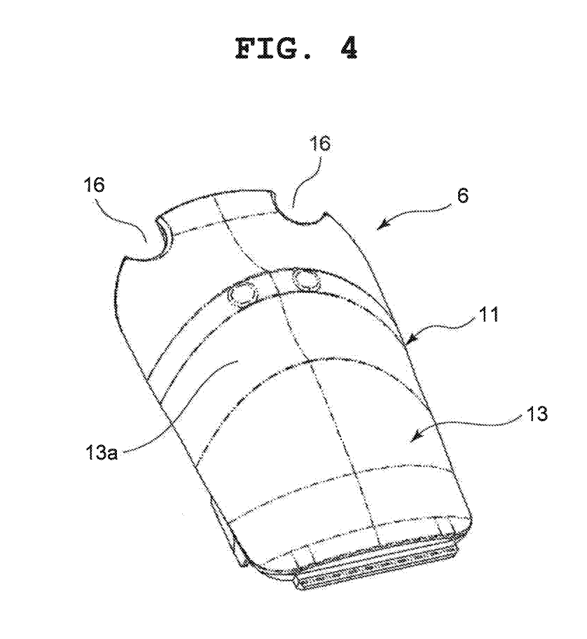

In this instance, the outer shape of the second cover section 14 is formed slightly larger than the opening section 7a of the battery storage section 7 provided in the lower case 3, and structured to come in contact with the outer edge portion of the opening section 7a of the battery storage section 7, as shown in FIG. 3. As shown in FIG. 2, and FIG. 4 to FIG. 7, a pair of attachment recess sections 16 are provided in corners on the sides of one end portion (end portion on the upper edge side in FIG. 2) of the second cover section 14, and a pair of attachment members 15 provided in the lower case 3 are respectively fitted in this pair of attachment recess sections 16.

The pair of attachment recess sections 16 are formed by each corner portion of the second cover section 14 being notched in a semicircular shape, and a brim section 16a is provided on the lower portion of the inner peripheral surface of the attachment recess section 16 formed by notching, as shown in FIG. 4 to FIG. 7, and FIG. 10. As a result, the outer cover section 11 is structured such that the pair of attachment members 15 of the lower case 3 is detachably inserted into the pair of attachment recesses 16 from the lateral direction, and the attachment members 15 are respectively arranged on the brim sections 16a, whereby the brim sections 16a are pressed against the lower case 3, and the outer cover section 11 is attached to the lower case 3.

In this instance, the pair of attachment members 15 is respectively structured to include an arm section 15a and a disk-shaped pressing section 15b, as shown in FIG. 2. The arm section 15a is attached to the undersurface (top surface in FIG. 2) of the lower case 3 in a manner to be rotatable in the planar direction, and the pressing section 15b is provided on the tip end portion of the arm section 15a. As a result, the pair of attachment members 15 is structured such that the arm sections 15a are rotated in the lateral direction (left-right direction in FIG. 2), and the pressing sections 15b are inserted into the attachment recesses 16 of the outer cover section 11 from the lateral direction, whereby the outer cover section 11 is pressed against the lower case 3.

On the other hand, the inner cover section 12 is made of a hard synthetic resin, such as ABS resin or PC, as in the case of the second cover section 14, and the inner cover section 12 is attached to the undersurface of the second cover section 14 of the outer cover section 11 by a plurality of screws 17, as shown in FIG. 3, and FIG. 5 to FIG. 7. The outer shape of the inner cover section 12 is formed substantially the same as or slightly smaller than the inner peripheral surface of the opening section 7a of the battery storage section 7 provided in the lower case 3, as shown in FIG. 3.

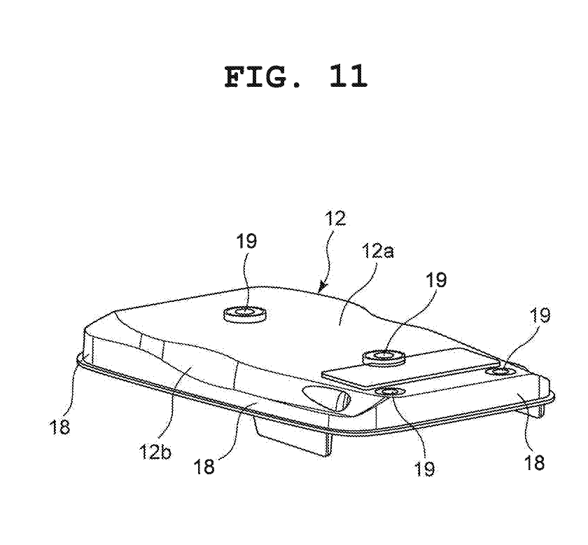

That is, the inner cover section 12 is constituted by an upper plate section 12a that is slightly smaller than the outer shape of the outer cover section 11 and a frame-shaped side plate section 12b that extends downwards from the edge portion of the upper plate section 12a, which are inserted into the opening section 7a of the battery storage section 7, as shown in FIG. 3, and FIG. 5 to FIG. 8. In this instance, a gasket groove 18 is circularly provided in the outer peripheral portion of the side plate section 12b, continuously along the outer periphery of the inner cover section 12, as shown in FIG. 11 to FIG. 13.

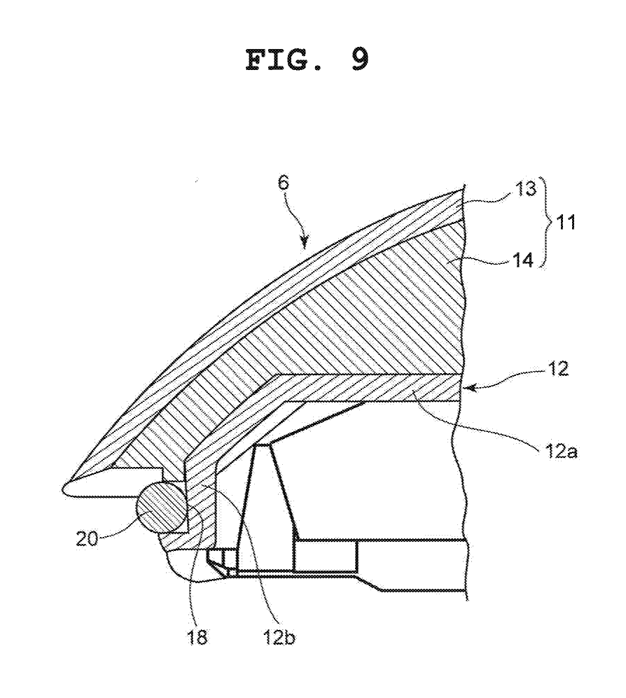

As shown in FIG. 8 and FIG. 9, this gasket groove 18 is a step-shaped, notched section formed in the outer peripheral surface of the inner cover section 12, and is open in two directions perpendicular to each other, toward the top surface side opposing the outer cover section 11 and the outer peripheral side of the inner cover section 12. As a result, the gasket groove 18 is structured such that the waterproofing gasket 20 is circularly fitted therein continuously along the outer periphery of the inner cover section 12, as shown in FIG. 5.

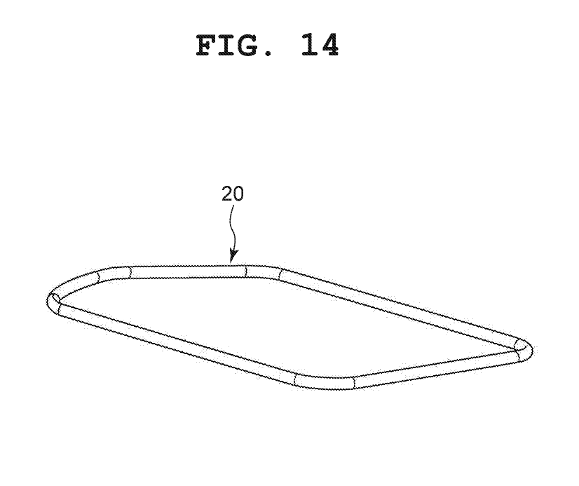

The waterproofing gasket 20 is an elastic member made of rubber or the like and is formed having a substantially circular cross-sectional shape, as shown in FIG. 14. In this instance, the waterproofing gasket 20 is formed slightly thicker than the depth of the gasket groove 18 in the circumferential direction so that, when the waterproofing gasket 20 is arranged in the gasket groove 18, a portion of the waterproofing gasket 20 protrudes outside of the outer peripheral side of the inner cover section 12 from inside the gasket groove 18, as shown in FIG. 8 and FIG. 9.

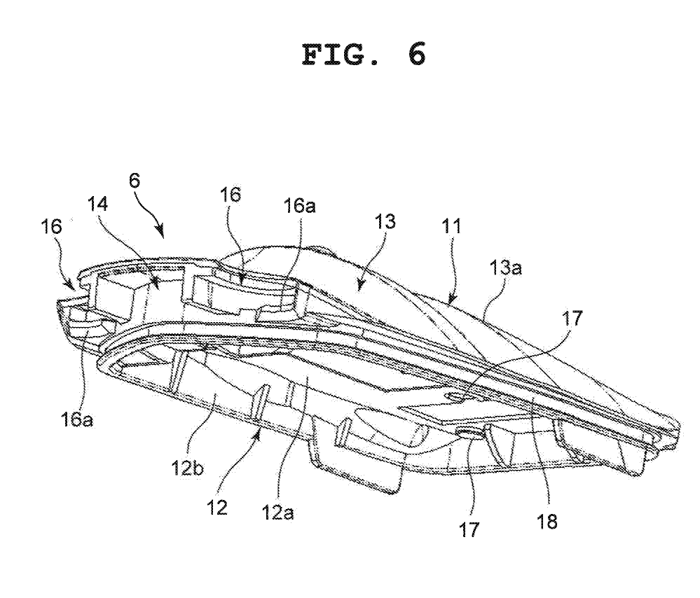

That is, the gasket groove 18 is structured such that, when the inner cover section 12 is attached to the undersurface of the second cover section 14 of the outer cover section 11, the top surface side of the gasket groove 18 is covered by the undersurface of the outer peripheral portion of the second cover section 14 of the outer cover section 11, whereby the gasket groove 18 is open only on the outer peripheral side of the inner cover section 12, as shown in FIG. 6, FIG. 8 and FIG. 9. As a result, when the waterproofing gasket 20 is fitted in the gasket groove 18, a portion of the waterproofing gasket 20 protrudes only toward the outer peripheral side of the inner cover section 12, as shown in FIG. 5, FIG. 8 and FIG. 9.

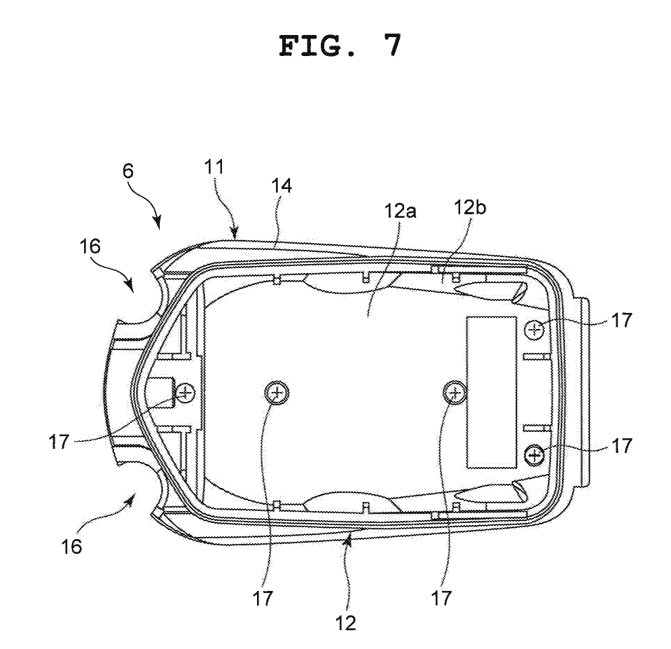

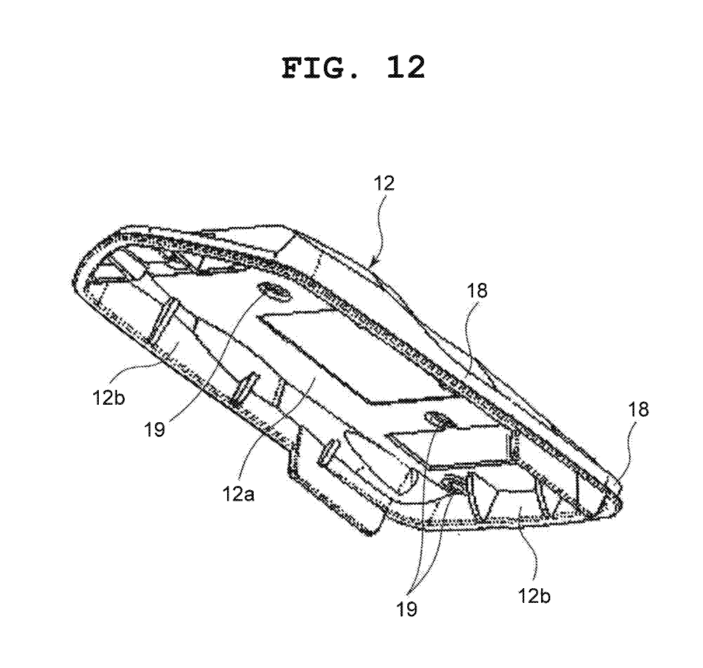

Also, a plurality of screw insertion holes 19 into which the plurality of screws 17 are inserted are provided in the upper plate section 12a of the inner cover section 12, corresponding to the plurality of boss sections 14b provided in the second cover section 14 of the outer cover section 11, as shown in FIG. 7, FIG. 11, and FIG. 12. Accordingly, the inner cover section 12 is structured such that the plurality of screws 17 are respectively inserted into the plurality of screw insertion holes 19 from below, screwed into the screw holes 14c of the plurality of boss sections 14b provided on the undersurface of the second cover section 14 of the outer cover section 11, and tightened, whereby the inner cover section 12 is attached to the outer cover section 11, as shown in FIG. 3 and FIG. 7. Next, the manufacturing of the battery cover 6 described above will be described.

In this instance, the outer cover section 11 and the inner cover section 12 are manufactured separately. First, in the manufacturing of the outer cover section 11, the first cover section 13 made of a soft synthetic resin such as rubber or elastomer, and the second cover section 14 made of a synthetic resin such as ABS resin or PC that is harder than the soft synthetic resin are integrally formed by two-color formation using a mold for molding.

At this time, for example, the second cover section 14 made of the hard synthetic resin is molded using a first mold for molding, and the second cover section 14 molded using the first mold for molding is place in a second mold for molding. Then, in this state, the first cover section 13 made of the soft synthetic resin is molded. As a result, the outer cover 11 in which the first cover section 13 and the second cover section 14 are integrally formed by two-color formation is manufactured.

In the manufacturing of the inner cover section 12, the hard synthetic resin such as ABS resin or PC is injected into a mold for molding, as in the case of the second cover section 14. At this time, the gasket groove 18 is formed in the outer peripheral portion of the inner cover section 12 continuously along the outer periphery of the inner cover section 12, while being open in two directions perpendicular to each other, toward the top surface side opposing the outer cover section 11 and the outer peripheral side of the inner cover section 12, as shown in FIG. 10 to FIG. 13.

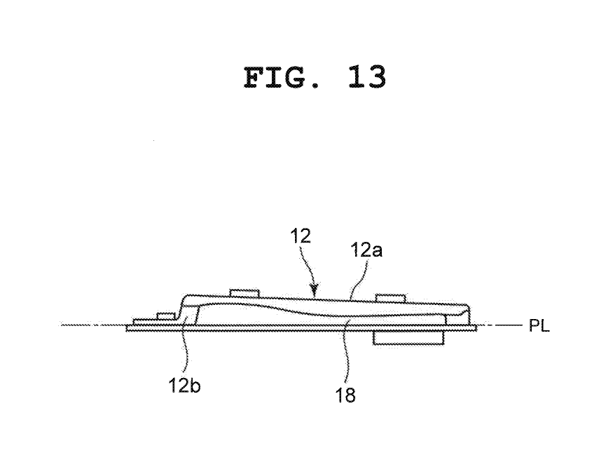

In this instance, the gasket groove 18 of the inner cover section 12 does not have an undercut shape or an overhang shape. Therefore, in the molding of the inner cover section 12 using a mold for molding, the inner cover section 12 can be demolded by being divided into an upper mold and a lower mold along a parting line (PL) in FIG. 13, without a slide mechanism being provided in the mold. Accordingly, the structure of the mold for molding is simple, and the inner cover section 12 can be easily molded using this mold for molding.

Next, the inner cover section 12 is attached to the outer cover section 11. At this time, the plurality of screws 17 are respectively inserted into the plurality of screw insertion holes 19 in the inner cover section 12 from below, screwed into the screw holes 14c of the plurality of boss sections 14b provided on the undersurface of the second cover section 14 of the outer cover section 11, and tightened, as shown in FIG. 3. As a result, the inner cover section 12 is attached to the outer cover section 11.

When the inner cover section 12 is attached to the outer cover section 11 as described above, the top surface side of the gasket groove 18 formed in the upper outer periphery of the inner cover section 12 is covered by the undersurface of the outer peripheral portion of the second cover section 14 of the outer cover section 11, as shown in FIG. 8 and FIG. 9. As a result, the gasket groove 18 is open only on the outer peripheral side of the inner cover section 12, as shown in FIG. 6. Then, the waterproofing gasket 20 is fitted in the gasket groove 18. At this time, the waterproofing gasket 20 is fitted in the gasket groove 18 such that a portion of the waterproofing gasket 20 protrudes towards the outer peripheral side of the inner cover section 12 from the gasket groove 18, as shown in FIG. 9.

Next, an instance will be described in which the battery cover 6 is attached to the lower case 3 and covers the opening section 7a of the battery storage section 7.

At this time, as shown in FIG. 3, the inner cover section 12 of the battery cover 6 is placed to correspond to the opening section 7a of the battery storage section 7 in the lower case 3, and inserted into the opening section 7a of the battery storage section 7, whereby the second cover section 14 of the outer cover section 11 comes in contact with the outer edge portion of the opening section 7a of the battery storage section 7.

As a result, a portion of the waterproofing gasket 20 fitted in the gasket groove 18 in the outer peripheral surface of the inner cover section 12 elastically comes in close contact with the inner peripheral surface of the opening section 7a of the battery storage section 7. Accordingly, the opening section 7a of the battery storage section 7 is sealed by the inner cover section 12. In this state, the battery cover 6 is fixed to the lower case 3 by the pair of attachment members 15 provided on the lower case 3, as shown in FIG. 2.

At this time, the respective arm sections 15a of the pair of attachment members 15 are rotated in the lateral direction, and the pressing sections 15b are respectively inserted from the lateral direction into the pair of attachment recess sections 16 provided in the outer cover section 11. As a result, the pressing sections 15b of the pair of attachment members 15 are arranged on the brim sections 16a respectively provided in the pair of attachment recess sections 16, and press the brim sections 16a against the lower case 3. Consequently, the battery cover 6 is attached to the lower case 3 while sealing the battery storage section 7.

In mobile information terminals such as this, their battery capacities may differ by unit type, and accordingly the size of the battery storage section 7 may also differ by unit type. However, even in cases like this, the difference in size can be easily accommodated simply by the inner cover section 12 being replaced according to the size of the opening section 7a of the battery storage section 7. That is, the difference in the size of the opening section 7a of the battery storage section 7 can be accommodated by the inner cover section 12 being removed from the outer cover section 11 by the removal of the screws 17, and replaced with another inner cover section according to the size of the opening section 7a of the battery storage section 7.

As described above, the battery cover 6 includes the outer cover section 11 that forms a portion of the outer shape of the device case 1, and the inner cover section 12 that is attached to the inner side of the outer cover section 11 and detachably inserted into the opening section 7a of the battery storage section 7. In addition, the gasket groove 18, which is open in two directions perpendicular to each other toward the outer cover section 11 side and the outer peripheral side of the inner cover section 12, is provided in the outer peripheral portion of the inner cover section 12 along the outer periphery of the inner cover section 12, so as to be located closer to the center side than the outer periphery of the outer cover section 11. Therefore, a mold for molding it can be manufactured with a simple structure at low cost. In addition, waterproofing can be ensured.

That is, in the battery cover 6, when the inner cover section 12 is attached to the inner side of the outer cover section 11, the gasket groove 18 formed in the outer peripheral portion of the inner cover section 12 is open only on the outer peripheral side of the inner cover section 12 by being covered by the outer peripheral portion of the outer cover section 11. Accordingly, the waterproofing gasket 20 is favorably and reliably fitted in the gasket groove 18 that is open only on the outer peripheral side of the inner cover section 12, whereby waterproofing can be ensured.

Moreover, in the molding of the inner cover section 12 using a mold for molding, a gasket groove having an undercut shape or an overhang shape is not required to be formed in the inner cover section 12. Therefore, demolding can be performed simply by the mold being parted along the parting line (PL), without a slide mechanism being provided in the mold. Accordingly, the mold for molding has a simple structure, and therefore the mold for molding and the inner cover section 12 can be manufactured at low cost. In addition, the area surrounding the gasket groove 18 can be made thick, and thereby be reinforced. Accordingly, the gasket groove 18 can be formed rigidly.

As a result, the waterproofing gasket 20 is favorably and reliably fitted in the gasket groove 18, and a portion of the waterproofing gasket 20 protrudes towards the outer peripheral side of the inner cover section 12 from the gasket groove 18. Accordingly, when the inner cover section 12 is inserted into the opening section 7a of the battery storage section 7, the portion of the waterproofing gasket 20 protruding from the gasket groove 18 favorably and reliably comes in elastic contact with the inner peripheral surface of the opening section 7a of the battery storage section 7, whereby the opening section 7a of the battery storage section 7 is reliably sealed and waterproofing is ensured.

Furthermore, in the battery cover 6, the outer cover section 11 and the inner cover section 12 are molded separately. Therefore, in the molding of the outer cover section 11 and the inner cover section 12, the shapes of the outer cover section 11 and the inner cover section 12 are less restricted by the gasket groove 18, compared to when the outer cover section 11 and the inner cover section 12 are integrally molded. Therefore, the outer cover section 11 and the inner cover section 12 can be shaped freely.

In this instance, the outer cover section 11 is structured by the first cover section 13 made of a soft synthetic resin having elasticity and the second cover section 14 made of a synthetic resin harder than the soft synthetic resin being formed by two-color formation, with the first cover section 13 being located on the outer side with respect to the lower case 3, and the second cover section 14 being located inside the first cover section 13. Therefore, the outer cover section 11, which has high shock-resistance, can be simply and easily manufactured.

That is, in the outer cover section 11, the first cover section 13 made of a soft synthetic resin having elasticity is provided on the outer side of the device case 1, and the second cover section 14 made of a hard synthetic resin is provided inside the first cover section 13. Therefore, when the outer cover section 11 suffers an impact from being dropped or the like, the first cover section 13 elastically absorbs the impact, and the second cover section 14 favorably and reliably receives the rest of the impact that has not been absorbed by the first cover section 13. As a result, the outer cover section 11 can withstand the impact of being dropped from a height of about two meters. Therefore, shock-resistance is significantly improved according to the present invention.

Still further, the outer surface of the first cover section 13 of the outer cover section 11 is formed into the curved surface 13a that is continuous with the undersurface of the lower case 3. Therefore, when the battery cover 6 is attached to the lower case 3 and the user grips the gripping section 1a of the device case 1, the first cover section 13 closely fits in the user's palm by the curved surface 13a of the first cover section 13. In this instance, because the first cover section 13 is formed by a synthetic resin having elasticity such as rubber or elastomer, the sense of touch of the battery cover 6 when the device case 1 is gripped is nice, and the device case 1 is easy to grip.

Yet still further, in the outer cover section 11, the reinforcement ribs 14a are provided vertically and horizontally on the surface of the second cover section 14 opposing the inner cover section 12. Therefore, even when the overall thickness of the second cover section 14 is thick, the thickness of the second cover 14 can be reduced by the reinforcement ribs 14a, and thereby the weight of the second cover section 14 can be reduced. In addition, even when the thickness is reduced, the strength of the second cover section 14 can be ensured by the reinforcement ribs 14a. Moreover, sink marks which may occur on the front surface (top surface in FIG. 12) of the second cover section 14 during the formation of the second cover section 14 can be reduced by the reinforcement ribs 14a. As a result, the second cover section 14 can be favorably formed.

Yet still further, in the battery cover 6, the outer cover section 11 and the inner cover section 12 are fixed to each other by the screws 17. Therefore, the outer cover section 11 and the inner cover section 12 can be easily attached. As a result, even when the battery capacities of mobile information terminals differ by unit type and therefore the size of the battery storage section 7 differs by unit type, the difference can be easily accommodated simply by the inner cover section 12 being removed from the outer cover section 11 and replaced with another inner cover section according to the size of the opening section 7a of the battery storage section 7.

In the above-described first embodiment, the battery cover 6 that covers the battery storage section 7 of the device case 1 is described as a cover member according to the present invention. However, the cover member is not necessarily required to be a battery cover. The present invention can be widely applied to various cover members that cover storage sections such as a terminal storage section of an external connection terminal or a card storage section for a memory card.

Additionally, in the above-described first embodiment, the present invention has been applied to a mobile information terminal. However, the present invention is not necessarily required to be applied to a mobile information terminal and can be widely applied to various mobile devices, such as mobile phones, electronic cameras, electronic dictionaries, and portable music players.

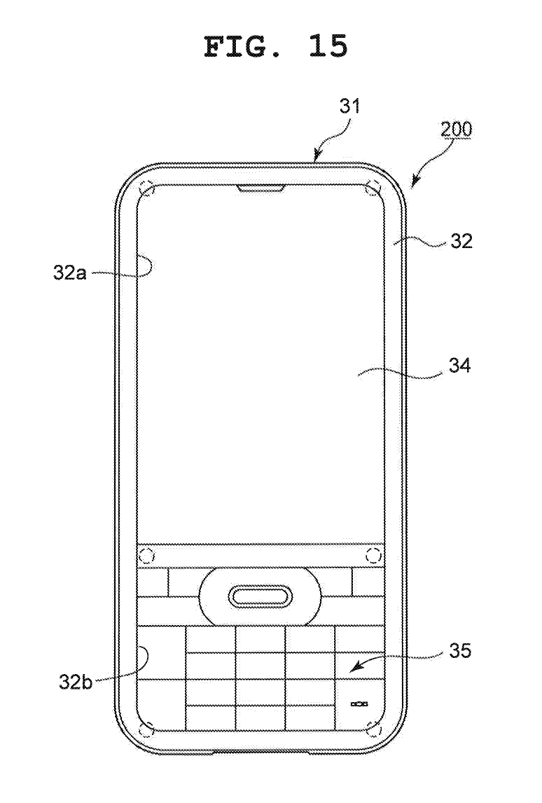

Hereinafter, a second embodiment in which the present invention has been applied to a mobile information terminal 200 will be described with reference to FIG. 15 to FIG. 27.

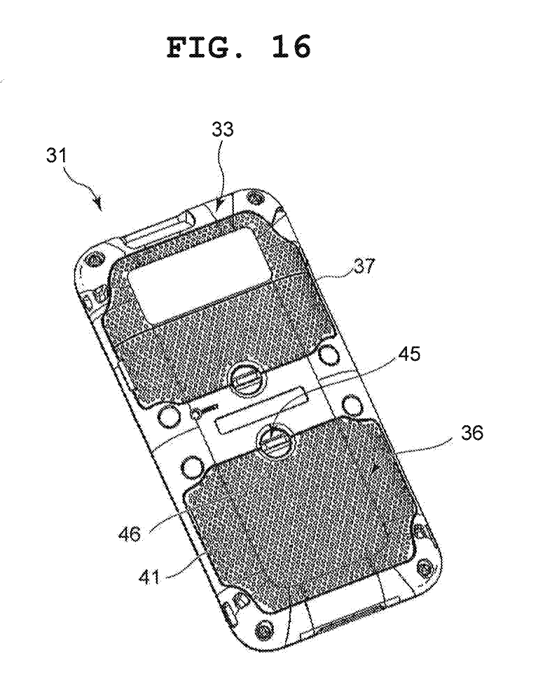

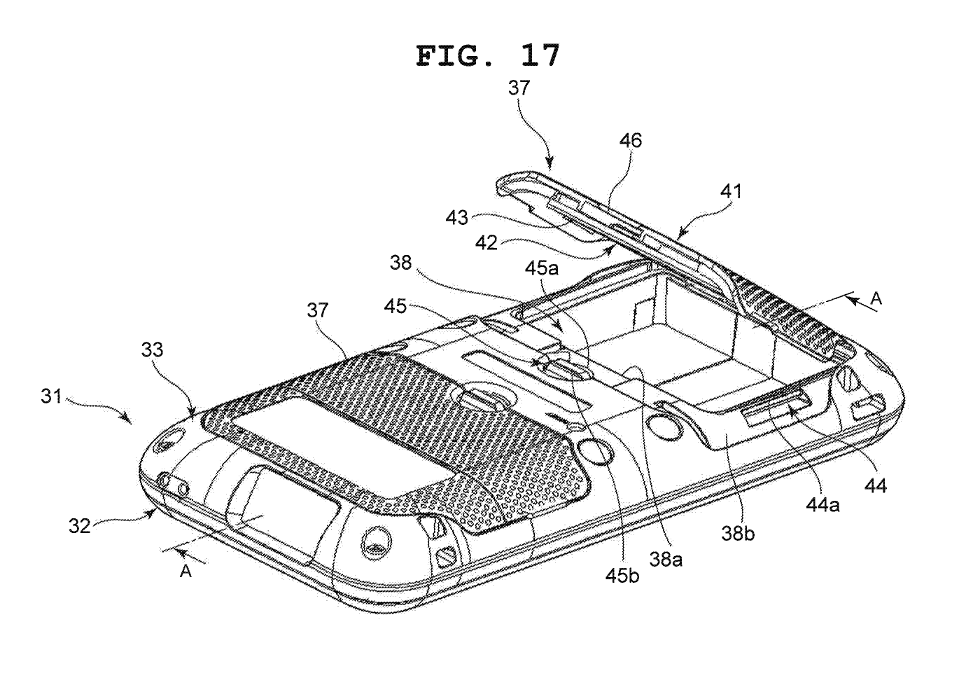

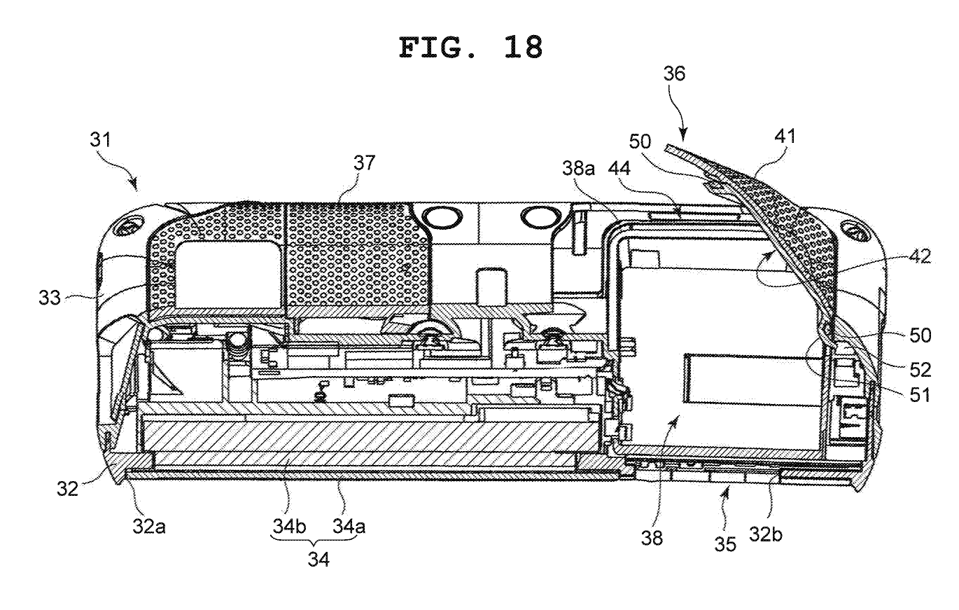

As shown in FIG. 15 and FIG. 16, the mobile information terminal 200 includes a device case 31. The device case 31 is constituted by an upper case 32 and a lower case 33, and an input display section 34 and a key input section 35 are provided inside the device case 31 such that they are exposed on the top surface side (undersurface side in FIG. 18) of the upper case 32, as shown in FIG. 15 and FIG. 18. In addition, a battery cover 36 and an inspection cover 37 are arranged on the undersurface (top surface in FIG. 16) of the lower case 33, as shown in FIG. 16 and FIG. 17.

In this instance, the input display section 34 includes a transparent touch panel 34a and a display panel 34b, as shown in FIG. 18. The transparent touch panel 34a is structured such that information is inputted by touch operations being performed on its surface. The display panel 34b is a flat-screen display panel, such as a liquid crystal display panel or an electroluminescent (EL) display panel, and is structured to electro-optically display various information related to information processing.

The input display section 34 is structured by the display panel 34b being arranged on the lower side (upper side in FIG. 18) of the transparent touch panel 34a, and is mounted inside the upper case 32. As a result, the input display section 34 is structured such that the transparent touch panel 34a is exposed on the upper side (lower side in FIG. 18) from a display opening section 32a of the upper case 32. The user views information displayed on the display panel 34b from above (below in FIG. 18) through the transparent touch panel 34a, and performs a touch operation on the transparent touch panel 34a while viewing the information displayed on the display panel 34b.

The key input section 35 includes various keys required for information processing, such as character keys, cursor keys, and function keys, as shown in FIG. 15, and is mounted inside the upper case 32, as shown in FIG. 18. The top surface (lower surface in FIG. 18) of the key input section 35 is exposed upwards (downwards in FIG. 18) from a key opening section 32b of the upper case 32. As shown in FIG. 17 and FIG. 18, a battery storage section 38 that stores a battery (not shown) is provided inside the lower case 33 so as to be open on the underside of the lower case 3 (upper side in FIG. 17 and FIG. 18), corresponding to the underside of the key input section 35 (upper side in FIG. 18).

The battery cover 36 is structured to openably and closably cover an opening section 38a of the battery storage section 38 provided in a portion of the lower case 33 corresponding to the key input section 35, as shown in FIG. 18. This battery cover 36 includes an outer cover section 41 that forms a portion of the outer shape of the lower case 33, and an inner cover section 42 that is attached to the inner side (underside in FIG. 17) of the outer cover section 41 and detachably inserted into the opening section 38a of the battery storage section 38 provided in the lower case 33, as shown in FIG. 14 to FIG. 20.

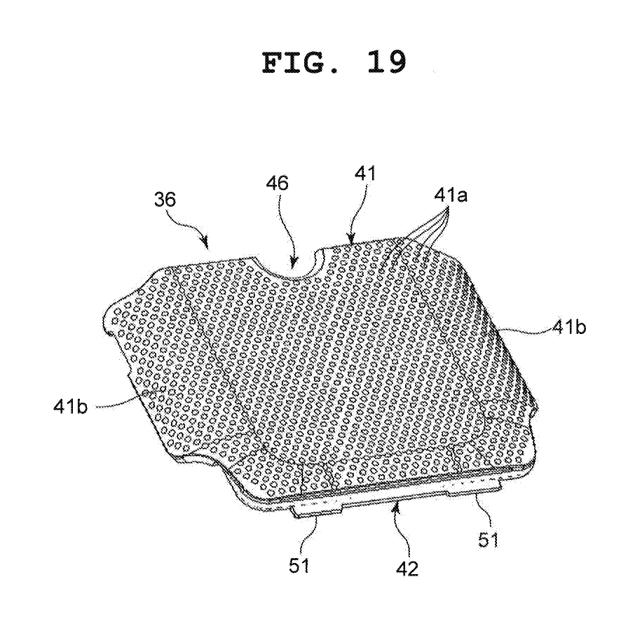

The outer cover section 41 is made of a synthetic resin, and numerous slip-stopping projection and recess sections 41a are provided on the outer surface (top surface in FIG. 19) of the outer cover section 41, as shown in FIG. 16 to FIG. 19. The side portions of the outer surface of the outer cover section 41 are formed into curved sections 41b that are continuous with the outer surface of the lower case 33. This outer cover section 41 is structured such that its outer shape is slightly larger than the opening section 38a of the battery storage section 38 provided in the lower case 33, and is arranged on the outer peripheral edge of the opening section 38a of the battery storage section 38, as shown in FIG. 17.

In this instance, a fitting recess section 38b, on which the peripheral edge portion of the outer cover section 41 including the curved sections 41b is arranged, is provided in the outer surface (top surface in FIG. 17) of the lower case 33, which is located around the periphery of the opening section 38a of the battery storage section 38, as shown in FIG. 17 and FIG. 18. Accordingly, when the outer cover section 41 covers the opening section 38a of the battery storage section 38, and the peripheral edge portion of the outer cover section 41 is arranged on the fitting recess section 38b of the lower case 33, the outer surface of the outer cover section 41 follows along the outer surface of the lower case 33, as shown in FIG. 16. As a result, when the user grips the device case 31, the device case 31 favorably fits in the user's palm.

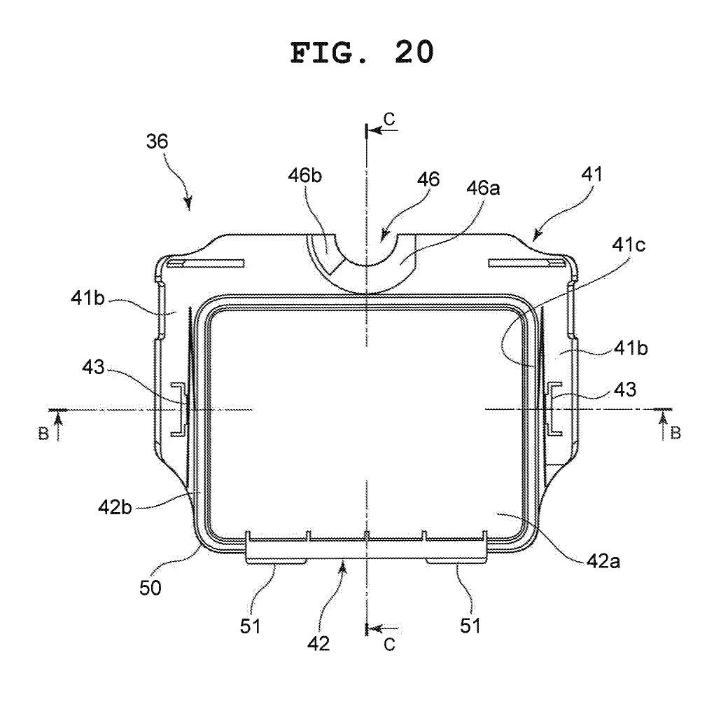

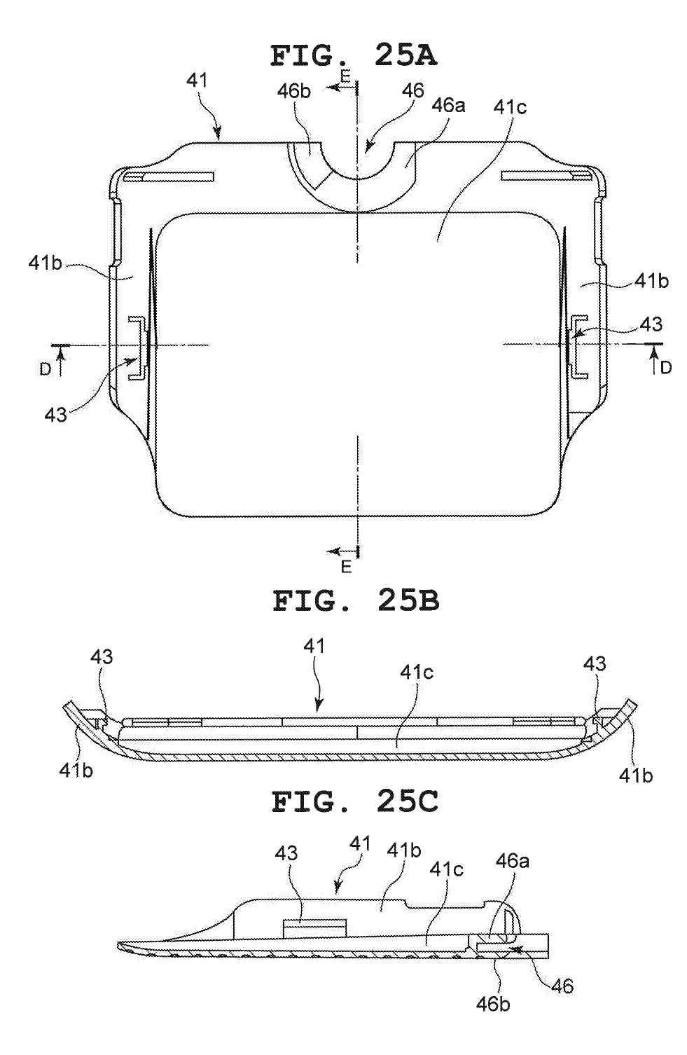

Also, on the inner surface of this outer cover section 41, a cover fitting recess section 41c in which the inner cover section 42 is arranged is provided to be open only on one side (lower edge portion in FIG. 25A) as shown in FIG. 25A to FIG. 25C, and a pair of engaging hook sections 43 is integrally formed on the side portions of the inner surface of the outer cover section 41 which are on the sides of the cover fitting recess section 41c in the left-right direction (in other words, the direction perpendicular to the longitudinal direction of the lower case 33), as shown in FIG. 20 to FIG. 22B, and FIG. 25A to FIG. 25C.

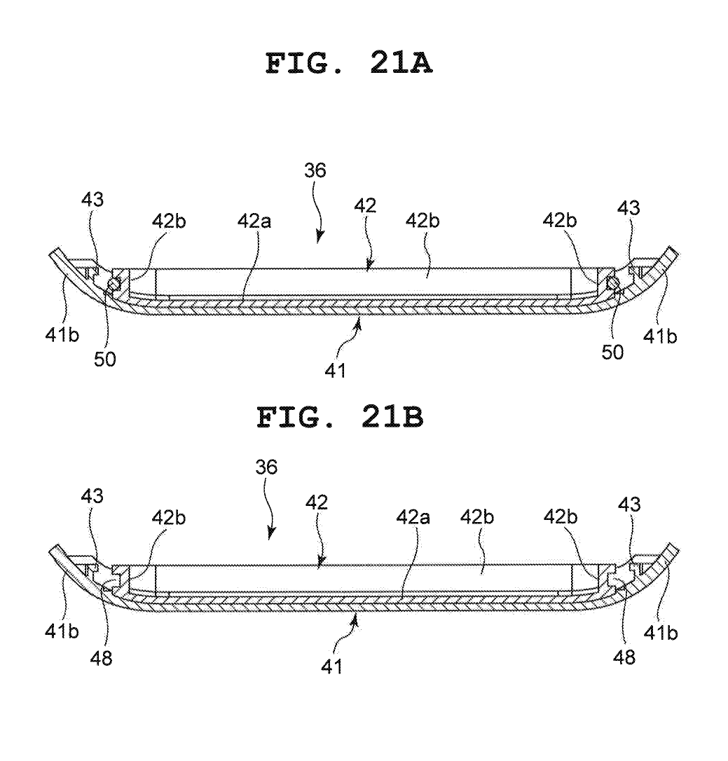

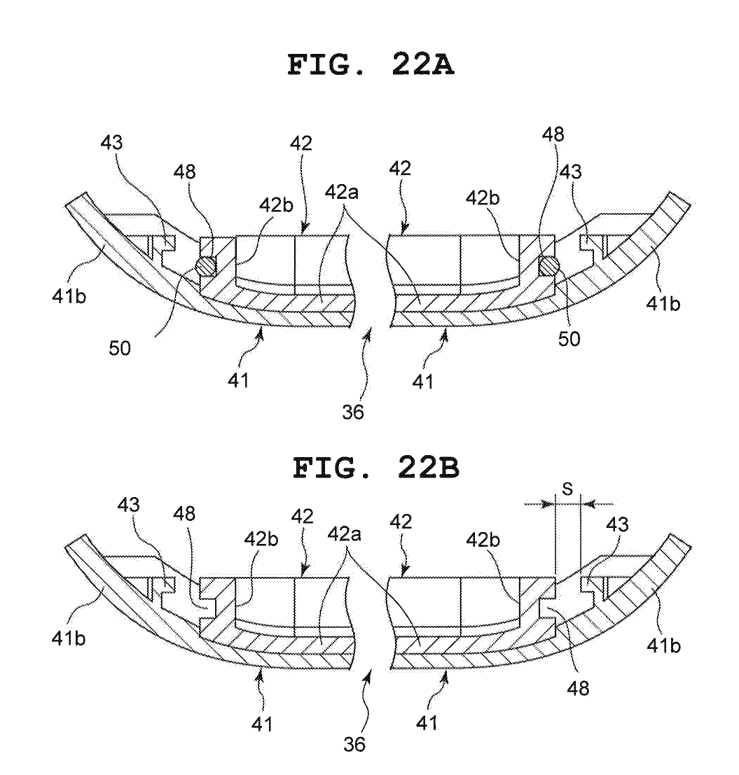

The pair of engaging hook sections 43 is structured to detachably engage with locking groove sections 44 provided in the fitting recess section 38b in the peripheral edge portion of the opening section 38a of the battery storage section 38, as shown in FIG. 17. That is, the pair of engaging hook sections 43 is shaped to extend downwards (upwards in FIG. 21A and FIG. 21B) from the inner surface of the curved sections 41b of the outer cover section 41, and the lower end portion (upper end portion in FIG. 21A and FIG. 21B) of each engaging hook section 43 projects toward the center of the outer cover section 41, or in other words, toward the outer peripheral surface of the inner cover section 42, as shown in FIG. 21A to FIG. 22B, and FIG. 25A to FIG. 25C.

The locking groove sections 44 of the lower case 33 are notched grooves respectively provided in the fitting recess section 38b in the peripheral edge portion of the opening section 38a of the battery storage section 38, and located in the side portions of the lower case 33, as shown in FIG. 17. A locking projection section 44a that locks the lower end portion of the engaging hook section 43 is provided in each of these notched grooves, as shown in FIG. 17.

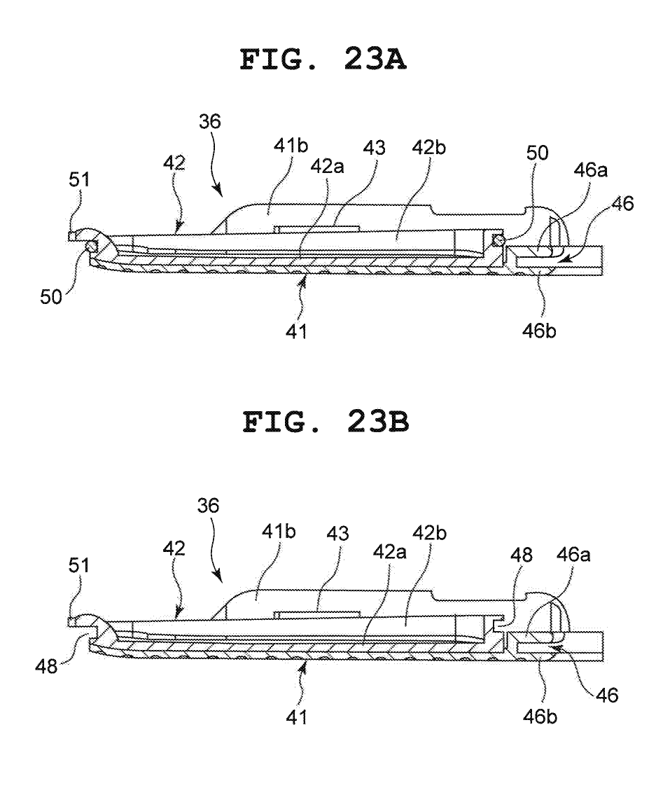

As shown in FIG. 16 and FIG. 17, a fixing groove section 46 is provided in a side portion (left side portion in FIG. 17) of the outer cover section 41 in the front-back direction (longitudinal direction of the lower case 33), which is used to fix the battery cover 36 to the lower case 33 by a fixing member 45 provided on the undersurface (top surface in FIG. 17) of the lower case 33. This fixing groove section 46 is formed by a side portion of the outer cover section 41 being notched into a substantially semicircular shape as shown in FIG. 19 and FIG. 20, and gripping brim sections 46a and 46b are respectively provided on the upper and lower portions of the inner peripheral surface of the fixing groove section 46 formed by notching, as shown in FIG. 23A to FIG. 25C.

In this instance, the fixing member 45 includes a disk section 45a, an engaging brim section (not shown), and an operating section 45b, as shown in FIG. 16 and FIG. 17. The disk section 45a is attached to the undersurface (top surface in FIG. 17) of the lower case 33 in a manner to be rotatable in the planar direction, and the engaging brim section is formed projecting from a predetermined area of the outer peripheral surface of the disk section 45a. The operating section 45b is provided on the top surface of the disk section 45a.

Accordingly, the fixing member 45 is structured such that, when the battery cover 36 is closed in a state where the disk section 45a has been rotated and thereby the engaging brim section has been separated from the battery storage section 38, the disk section 45 is relatively inserted into the fixing groove section 46 of the outer cover section 41, and when the operating section 45b is operated and the disk section 45a is rotated in this state, the engaging brim section (not shown) of the disk section 45a is inserted between the upper and lower gripping brim sections 46a and 46b of the fixing groove section 46 of the outer cover 41, whereby the outer cover section 41 is fixed to the lower case 33.

On the other hand, the inner cover section 42 is made of a synthetic resin as in the case of the outer cover section 41, and fixed in the cover fitting recess section 41c provided on the inner surface of the outer cover section 41 by an adhesive, by welding, or the like, as shown in FIG. 20 to FIG. 24B. The outer shape of the inner cover section 42 is substantially the same as or slightly smaller than the inner peripheral surface of the opening section 38a of the battery storage section 38, as shown in FIG. 17 and FIG. 20.

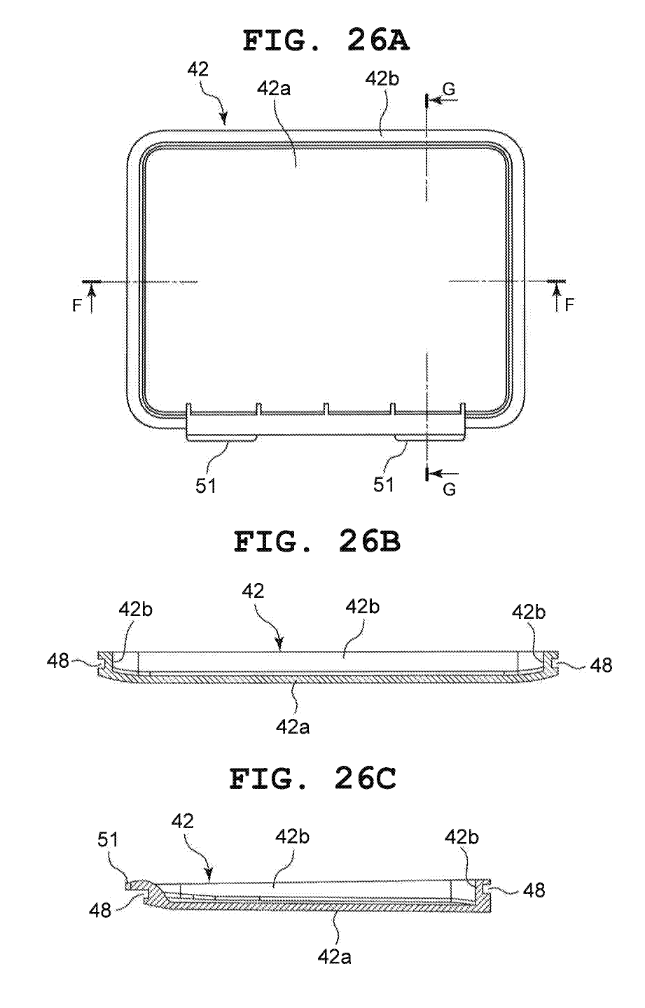

Specifically, the inner cover section 42 is structured such that a plate section 42a formed to be substantially the same size as the cover fitting recess section 41c of the outer cover section 41 and a frame section 42b formed extending downwards (extending upwards in FIG. 26B and FIG. 26C) on the periphery of the plate section 42a are integrally formed, and inserted into the opening section 38a of the battery storage section 38, as shown in FIG. 20, FIG. 26A and FIG. 26B. In this instance, a gasket groove 48 is provided in the outer peripheral portion of the frame section 42b continuously in a ring shape, along the outer periphery of the inner cover section 42, as shown in FIG. 26A to FIG. 26C.

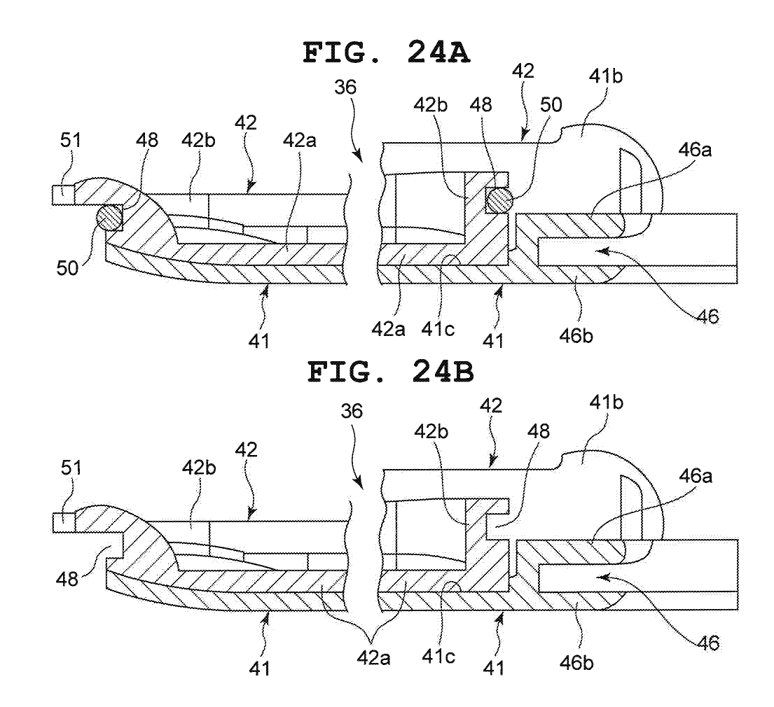

The gasket groove 48, which is a recess section having a rectangular cross-sectional shape and formed in the outer peripheral surface of the inner cover section 42, is structured to be open towards the outer peripheral side of the inner cover section 42, and opposed and located close to the pair of engaging hook sections 43 of the outer cover section 41, as shown in FIG. 21A to FIG. 23B, and FIG. 26A and FIG. 26B. As shown in FIG. 20, FIG. 22A, and FIG. 24A, a waterproofing gasket 50 is fitted in this gasket groove 48 continuously in a ring shape, along the outer periphery of the inner cover section 42.

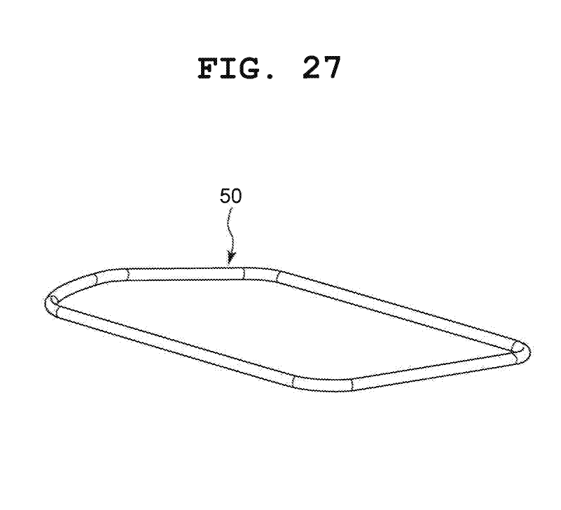

The waterproofing gasket 50 is an elastic member made of rubber or the like, and formed having a substantially circular cross-sectional shape, as shown in FIG. 27. In this instance, the waterproofing gasket 50 is formed slightly thicker than the depth of the gasket groove 48 in the circumferential direction so that, when the waterproofing gasket 50 is arranged in the gasket groove 48, a portion of the waterproofing gasket 50 projects outside of the outer peripheral side of the inner cover section 42 from within the gasket groove 48, as shown in FIG. 22A and FIG. 24A.

As shown in FIG. 17, FIG. 19, and FIG. 20, a pair of support projections 51 projecting in a lateral direction (towards the front in FIG. 20) are provided on a side portion (lower edge portion in FIG. 20) of the inner cover section 42 in the front-back direction (longitudinal direction of the lower case 33), or in other words, on the opposite side of the fixing groove section 46 of the outer cover section 41. The pair of support projections 51 serves as a rotation fulcrum of the battery cover 36 when the battery cover 36 covers the battery storage section 38.

Specifically, the pair of support projections 51 are structured to project in the lateral direction from the outer surface below (above in FIG. 24A and FIG. 24B) the gasket groove 48 of the frame section 42b of the inner cover section 42 as shown in FIG. 24A and FIG. 24B, and detachably inserted into and held in locking hole sections 52 provided on the inner peripheral surface of the opening section 38a of the battery storage section 38 when the battery cover 36 is attached to the battery storage section 38, as shown in FIG. 18.

As a result, when the pair of support projections 51 provided on the outer peripheral portion of the inner cover section 42 are inserted into and held in the locking hole sections 52 of the battery storage section 38, and the inner cover section 42 is rotated around the pair of support projections 51 for the battery cover 36 to cover the battery storage section 38, the inner cover section 42 is inserted into the opening section 38a of the battery storage section 38, and the outer peripheral edge portion of the outer cover section 41 including the curved sections 41b is arranged in the fitting recess section 38b provided in the periphery of the opening section 38a of the battery storage section 38, as shown in FIG. 17 and FIG. 18.

Next, the manufacturing of the battery cover 36 described above will be described.

In this instance, the outer cover section 41 and the inner cover section 42 are manufactured separately. First, in the manufacturing of the outer cover section 41, the outer cover section 41 is molded using a first mold for molding. At this time, the engaging hook sections 43 of the outer cover section 41 are shaped to extend downward (upward in FIG. 25B) from the curved sections 41b of the outer cover section 41, and their lower end portions (upper end portions in FIG. 25B) are shaped to project towards the center of the outer cover section 41, or in other words, towards the outer peripheral surface of the inner cover section 42.

The fixing groove section 46 located in a side portion (right side portion in FIG. 25C) of the outer cover section 41 is shaped such that the upper and lower gripping brim sections 46a and 46b, into which the locking brim section (not shown) of the fixing member 45 is detachably inserted, are formed. As a result, the engaging hook sections 43 and the fixing groove section 46 of the outer cover section 41 have a so-called undercut shape or an overhang shape.

Accordingly, a slide mechanism has been provided in the first mold for molding to form the engaging hook sections 43 and the fixing groove section 46. Consequently, by a slide core of the slide mechanism being slid when resin is injected into the first mold and the outer cover section 41 is demolded, the engaging hook sections 43 and the fixing groove section 46 are formed integrally with the outer cover section 41.

On the other hand, when forming the inner cover section 42, the inner cover section 42 is formed using a second mold for molding. At this time, the gasket groove 48 that is continuous along the outer peripheral surface of the frame section 42b of the inner cover section 42 is shaped to be open in the outward direction from the outer peripheral surface of the frame section 42b. As a result, the gasket groove 48 of the inner cover section 42 also has an undercut shape or an overhang shape. Accordingly, in the second mold for molding the inner cover section 42 as well, a slide mechanism has been provided, in order to form the gasket groove 48. Consequently, in a manner similar to that of the outer cover section 41, the inner cover section 42 is molded using the second mold.

Next, the inner cover section 42 is fixed to the inner surface of the outer cover section 41 by an adhesive or solvent welding. At this stage, as shown in FIG. 20, the plate section 42a of the inner cover section 42 is arranged in the cover fitting recess section 41c provided on the inner surface of the outer cover section 41, and a side portion (upper edge portion in FIG. 20) of the inner cover section 42 is placed close to the fixing groove section 46 of the outer cover section 41. In addition, the pair of support projections 51 of the inner cover section 42 projects beyond a side portion (lower edge portion in FIG. 20) of the outer cover section 41.

In this state, when the inner cover section 42 is fixed to the inner surface of the outer cover section 41, the pair of engaging hook sections 43 of the outer cover section 41 and the gasket groove 48 of the frame section 42b of the inner cover section 42 are opposed and located close to each other, as shown in FIG. 20 to FIG. 22B. In this instance, a space S between the pair of engaging hook sections 43 of the outer cover section 41 and the gasket groove 48 of the frame section 42b of the inner cover section 42 is narrow, and therefore even if the manufacturer tries to form the outer cover section 41 and the inner cover section 42 integrally by a singe mold for molding, a slide mechanism cannot be provided in the mold.

However, in this embodiment, the outer cover section 41 and the inner cover section 42 are formed separately. Accordingly, the space S between the pair of engaging hook sections 43 of the outer cover section 41 and the gasket groove 48 of the frame section 42b of the inner cover section 42 can be set narrow, by being adjusted when the inner cover section 42 is fixed to the outer cover section 41.

Next, an instance will be described in which the battery cover 36 described above is attached to the lower case 33 and covers the opening section 38a of the battery storage section 38.

At this stage, first, the waterproofing gasket 50 is fitted in the gasket groove 48 of the frame section 42b of the inner cover section 42. Then, the inner cover section 42 of the battery cover 36 is placed corresponding to the opening section 38a of the battery storage section 38 in the lower case 33, and the pair of support projections 51 of the inner cover section 42 are inserted to the locking hole sections 52 (see FIG. 18) of the battery storage section 38, as shown in FIG. 17 and FIG. 18.

In this state, the battery cover 36 is rotated around the pair of support projections 51, and the inner cover section 42 is inserted into the opening section 38a of the battery storage section 38, whereby the peripheral edge portion of the outer cover section 41 including the curved sections 41b is arranged in the fitting recess section 38b provided in the periphery of the opening section 38a of the battery storage section 38. At this time, a portion of the waterproofing gasket 50 fitted in the gasket groove 48 in the outer peripheral surface of the inner cover section 42, which projects outside, elastically comes in close contact with the inner peripheral surface of the opening section 38a of the battery storage section 38. As a result, the inner cover section 42 is inserted into the opening section 38a of the battery storage section 38 while being guided by the elastic contact of the waterproofing gasket 50. Accordingly, the overall battery cover 36 is guided.

In addition, when the peripheral edge portion of the outer cover section 41 including the curved sections 41b is arranged in the fitting recess section 38b provided in the periphery of the opening section 38a of the battery storage section 38, the pair of engaging hook sections 43 provided on the inner surface of the outer cover section 41 are locked by the pair of locking groove sections 44 which is provided in the fitting recess section 38b in the peripheral edge portion of the opening section 38a of the battery storage section 38 and located in the side portions of the lower case 33, as shown in FIG. 17. As a result, the battery cover 36 is attached to the lower case 33, covering the opening section 38a of the battery storage section 38 and thereby sealing the battery storage section 38.

Accordingly, the disk section 45a of the fixing member 45 provided in the lower case 33 is relatively inserted into the fixing groove section 46 that has a semicircular shape and is provided in one end portion of the outer cover section 41, as shown in FIG. 16 and FIG. 17. In this state, when the disk section 45a is rotated by a predetermined angle by the operating section 45b provided on the top surface of the disk section 45a being rotated by the user's fingers, the engaging brim section (not shown) of the disk section 45a is inserted between the upper and lower gripping brim sections 46a and 46b of the fixing groove section 46 of the outer cover section 41. Consequently, the outer cover section 41 is further firmly fixed to the lower case 33.

As a result, the battery cover 36 is firmly and reliably attached to the lower case 33 by the pair of engaging hook sections 43 being engaged with the pair of locking groove sections 44 of the lower case 33, the pair of support projections 51 being inserted into and held in the locking hole sections 52 of the opening section 38a of the battery storage section 38, and the fixing groove section 46 being fixed by the fixing member 45. Note that, when removing the battery cover 36, the user can easily remove this cover by performing the above-described operations in reverse.

As described above, the battery cover 36 includes the outer cover section 41 that forms a portion of the outer shape of the lower case 33, and the inner cover section 42 that is attached to the inner side of the outer cover section 41 and detachably inserted into the opening section 38a of the battery storage section 38. In addition, the pair of engaging hook sections 43, which detachably engage with the pair of locking groove sections 44 that are respectively provided in the outer side portions of the lower case 33 and located on the sides of the battery storage section 38, are formed on the inner surface of the outer cover section 41, and the gasket groove 48 which is opposed and located close to the pair of engaging hook sections 43 of the outer cover section 41 is formed in the outer peripheral portion of the inner cover section 42 continuously along the entire periphery. Therefore, the structure is simple and can be easily manufactured. In addition, waterproofing is ensured.

That is, after the waterproofing gasket 50 is fitted in the gasket groove 48 of the inner cover section 42 fixed to the inner surface of the outer cover section 41, when the inner cover section 42 is inserted into the opening section 38a of the battery storage section 38 of the lower case 33, and the outer cover section 41 is pressed against the lower case 33 for the battery cover 36 to cover the battery storage section 38 of the lower case 33, the waterproofing gasket 50 comes in close contact with the inner peripheral surface of the opening section 38a of the battery storage section 38, and the pair of engaging hook sections 43 of the outer cover section 41 are engaged with the pair of locking groove sections 44 provided in the outer side portions in the sides of the lower case 33.

In this instance, the battery cover 36 is structured such that the engaging hook sections 43 of the outer cover section 41 and the gasket groove 48 provided in the frame section 42b of the inner cover section 42 are opposed and located close to each other. Therefore, when the engaging hook sections 43 of the outer cover section 41 engage with the locking groove sections 44 of the lower case 33, the waterproofing gasket 50 fitted in the gasket groove 48 is reliably and firmly pressed against the inner peripheral surface of the battery storage section 38 by the engaging force of the engaging hook sections 43 in relation to the locking groove sections 44 of the lower case 33, whereby waterproofing is enhanced.

As a result, waterproofing is ensured with a simple structure in which a single waterproofing gasket 50 is fitted in the gasket groove 48 of the inner cover section 42. In addition, the battery cover 36 can be easily and reliably attached to the lower case 33 simply by the engaging hook sections 43 of the outer cover section 41 engaging with the locking groove sections 44 of the lower case 33. Accordingly, the waterproofing gasket 50 is favorably and reliably pressed against the inner peripheral surface of the battery storage section 38, whereby waterproofing is reliably maintained.

Moreover, since the outer cover section 41 and the inner cover section 42 can be molded separately, manufacturing can be simplified and facilitated even for the structure in which the engaging hook sections 43 of the outer cover section 41 and the gasket groove 48 provided in the frame section 42b of the inner cover section 42 are opposed and located close to each other, and the outer cover section 41 and the inner cover section 42 can be shaped freely. As a result, a battery cover that is excellent in appearance and design can be made. In addition, the device case 31 can be made to be easy to grip, user-friendly, compact and thin.

In this instance, the engaging hook sections 43 of the outer cover section 41 are located around the outer periphery of the inner cover section 42 and project towards the gasket groove 48 of the inner cover section 42. The gasket groove 48 of the inner cover section 42, which is open outwards from the outer peripheral surface of the inner cover section 42, is opposed and located close to the engaging hook sections 43. As a result, when the battery cover 36 covers the battery storage section 38, the waterproofing gasket 50 fitted within the gasket groove 48 is favorably and reliably pressed against the inner peripheral surface of the opening section 38a of the battery storage section 38.

That is, as a result of the engaging hook sections 43 of the outer cover section 41 and the gasket groove 48 of the inner cover section 42 being opposed and located close to each other, when the engaging hook sections 43 of the outer cover section 41 engage with the locking groove sections 44 of the lower case 33, the waterproofing gasket 50 fitted in the gasket groove 48 is firmly and reliably pressed against the inner peripheral surface of the battery storage section 38 by the engaging force of the engaging hook sections 43 in relation to the locking groove sections 44 of the lower case 33, whereby waterproofing is further enhanced.

In the manufacturing of the battery cover 36, the outer cover section 41 is molded by a slide mechanism for forming the engaging hook sections 43 being provided in the first mold for molding the outer cover section 41, and the inner cover section 42 is molded by a slide mechanism for forming the gasket groove 48 of the frame section 42b being provided in the second mold for molding the inner cover section 42, and fixed to the molded outer cover section 41. As a result, manufacturing can be simplified and facilitated even for the structure in which the engaging hook sections 43 of the outer cover 41 and the gasket groove 48 provided in the frame section 42b of the inner cover section 42 are opposed and located close to each other.

Moreover, in the battery cover 36, the waterproofing gasket 50 that comes in elastic contact with the inner peripheral surface of the opening section 38a of the battery storage section 38 of the lower case 33 is circularly fitted in the gasket groove 48 of the inner cover section 42. Therefore, when the inner cover section 42 is inserted into the opening section 38a of the battery storage section 38, a portion of the waterproofing gasket 50 projecting from the gasket groove 48 is favorably and reliably comes in elastic contact with the inner peripheral surface of the opening section 38a of the battery storage section 38. As a result, the opening section 38a of the battery storage section 38 is reliably sealed, and thereby waterproofing is ensured.

Furthermore, in the battery cover 36, the pair of support projections 51 which are detachably inserted into the locking hole sections 52 provided in the inner peripheral surface of the opening section 38a of the battery storage section 38, and serve as the rotation fulcrum of the inner cover section 42 are formed on a side portion of the inner cover section 42 which is perpendicular to the sides of the outer cover section 41 where the pair of engaging hook sections 43 on the outer peripheral portion are provided. As a result, the battery cover 36 is easily and favorably attached to the lower case 33 by the battery cover 36 being rotated with the pair of support projections 51 serving as the fulcrum.

That is, in the battery cover 36, when the pair of support projections 51 of the inner cover 42 are inserted into the locking hole sections 52 provided in the inner peripheral surface of the opening section 38a of the battery storage section 38, and the inner cover section 42 is moved toward the opening section 38a of the battery storage section 38 by the battery cover 36 being rotated around the pair of support projections 51, the waterproofing gasket 50 fitted in the gasket groove 48 of the inner cover section 42 comes in close contact with the inner peripheral surface of the opening section 38a of the battery storage section 38, whereby the inner cover section 42 is smoothly and favorably inserted into the opening section 38a of the battery storage section 38 while being guided by the waterproofing gasket 50.

Also, at this time, the pair of engaging hook sections 43 of the outer cover section 41 engages with the locking groove sections 44 provided in the fitting recess section 38b in the peripheral edge portion of the battery storage section 38. Therefore, the battery cover 36 is reliably attached to the lower case 33 with the battery cover 36 covering the opening section 38a of the battery storage section 38. In addition, the peripheral edge portion of the outer cover section 41 including the curved sections 41b is favorably arranged in the fitting recess section 38b in the peripheral edge portion of the battery storage section 38. Consequently, the battery cover 36 is easily and reliably attached to the lower case 33, and favorably covers the battery storage section 38.

Still further, in the battery cover 36, the fixing groove section 46, which is open outwards from the outer peripheral surface of the outer cover section 41 and fixed to the lower case 33 by the fixing member 45 provided in the lower case 33, is formed in a side portion of the outer cover section 41 located on the opposite side of a side portion of the inner cover section 42 where the support projections 51 are provided. Therefore, the battery cover 36 is further firmly fixed to the lower case 33 by the fixing groove section 46 being fixed by the fixing member 45.

In this instance, the fixing groove section 46 is a notched groove formed into a semicircular shape, and the gripping brim sections 46a and 46b are provided above and below the inner peripheral surface of the fixing groove section 46. In addition, the fixing member 45 includes the disk section 45a rotatably attached to the lower case 33, the engaging brim section (not shown) provided on the outer peripheral surface of the disk section 45a, and the operating section 45b provided on the top surface of the disk section 45a. As a result, the battery cover 35 is easily fixed to the lower case 33 simply by the operating section 45b being operated to rotate the disk section 45a, and the engaging brim section being inserted between the upper and lower gripping brim sections 46a and 46b of the fixing groove section 46.

Consequently, the battery cover 36 is reliably fixed to the lower case 33 in that even when suffering an impact from being dropped or the like and the pair of engaging hook sections 43 of the outer cover section 41 are disengaged from the locking groove sections 44 provided in the fitting recess section 38b in the peripheral edge portion of the battery storage section 38, the battery cover 36 is prevented from being detached from the lower case 33 by the pair of support projections 51 of the inner cover section 43 inserted into the locking hole sections 52 of the opening section 38a of the battery storage section 38, and the fixing groove section 46 of the outer cover section 41 fixed by the fixing member 45.

In the above-described second embodiment, the battery cover 36 that covers the battery storage section 38 of the device case 31 is described as a cover member according to the present invention. However, the cover member is not necessarily required to be a battery cover, and can be widely applied to various cover members such as an inspection cover 37 that covers an opening section used for inspection or other cover members that cover a variety of storage sections including a terminal storage section of an external connection terminal or a card storage section for a memory card.

Additionally, in the above-described second embodiment, the present invention has been applied to a mobile information terminal. However, the present invention is not necessarily required to be applied to a mobile information terminal and can be widely applied to various mobile devices, such as mobile phones, electronic cameras, electronic dictionaries, and portable music players.

While the present invention has been described with reference to the preferred embodiments, it is intended that the invention be not limited by any of the details of the description therein but includes all the embodiments which fall within the scope of the appended claims.

What is claimed is:

1. A mobile device comprising:
a cover member which covers an opening section of a storage section provided in a device case,
wherein the cover member includes an outer cover section which forms a portion of outer shape of the device case, and an inner cover section which is attached to inner side of the outer cover section and detachably inserted into the opening section of the storage section, and
a gasket groove which is open in two directions perpendicular to each other toward an outer cover section side and an outer peripheral side of the inner cover section is provided in an outer peripheral portion of the inner cover section along outer periphery of the inner cover section, so as to be located closer to a center side than outer periphery of the outer cover section.

2. The mobile device according to claim 1, wherein the outer cover section includes a first cover section made of a soft synthetic resin having elasticity and a second cover section made of a synthetic resin that is harder than the soft synthetic resin, which are formed by two-color formation with the first cover section being located on outer side of the device case and the second cover section being located on inner side of the first cover section.

3. The mobile device according to claim 2, wherein the second cover section of the outer cover section has reinforcement ribs vertically and horizontally provided on a surface opposing the inner cover section.

4. The mobile device according to claim 1, wherein the outer cover section and the inner cover section are fixed to each other by a screw member.

5. A mobile device comprising:
a cover member which covers an opening section of a storage section provided in a device case,
wherein the cover member includes an outer cover section which forms a portion of outer shape of the device case, and an inner cover section which is fixed to inner side of the outer cover section and detachably inserted into the opening section of the storage section,
engaging hook sections are formed on inner surface of the outer cover section, which detachably engage with locking groove sections which are respectively provided in outer side portions of the device case and located on sides of the storage section, and
a gasket groove is circularly formed in an outer peripheral portion of the inner cover section along entire periphery, which is opposed and located close to the engaging hook sections of the outer cover section.

6. The mobile device according to claim 5, wherein the engaging hook sections of the outer cover section are located around outer periphery of the inner cover section and project towards the gasket groove of the inner cover section, and the gasket groove of the inner cover section is open outwards from outer peripheral surface of the inner cover section, and opposed and located close to the engaging hook sections.

7. The mobile device according to claim 5, wherein the gasket groove of the inner cover section has a waterproof gasket circularly and continuously fitted therein which comes in elastic contact with inner peripheral surface of the opening section of the storage section.

8. The mobile device according to claim 5, wherein the inner cover section has a support projection formed on a side portion thereof which is detachably inserted into a locking hole section provided in inner peripheral surface of the opening section of the storage section and serves as a rotation fulcrum of the inner cover section.

9. The mobile device according to claim 8, wherein the outer cover section has a fixing groove section formed in a side portion thereof located on an opposite side of the side portion of the inner cover section where the support projection is formed, which is fixed to the device case by a fixing member provided in the device case.
